(19) United States
(12) Patent Application Publication
(10) Pub. No.: US 2015/0249184 A1
(43) Pub. Date: Sep. 3, 2015

(54) Semiconductor Multilayer Structure And Semiconductor Element

(71) Applicants: TAMURA CORPORATION, Tokyo (JP); KOHA CO., LTD., Tokyo (JP)

(72) Inventor: Shinkuro SATO, Tokyo (JP)

(21) Appl. No.: 14/633,099

(22) Filed: Feb. 26, 2015

(30) Foreign Application Priority Data
Feb. 28, 2014 (JP) 2014-039783

(51) Int. Cl. H01L 33/16; H01L 33/12; H01L 33/32

(52) U.S. Cl. CPC H01L 33/16; H01L 33/32; H01L 33/12

(57) ABSTRACT

A semiconductor multilayer structure includes a β-Ga₂O₃-based single crystal substrate including a main surface including a (−201), (101), (310) or (3-10) plane, the β-Ga₂O₃-based single crystal substrate being free from any twinning plane or further including a region free from any twinning plane, the region including a maximum width of not less than 2 inches in a direction perpendicular to an intersection line between a twinning plane and the main surface, and a nitride semiconductor layer including an AlₓGa_{y}In_{z}N (0≦x≦1, 0≦y≦1, 0≦z≦1, x+y+z=1) crystal epitaxially grown on the β-Ga₂O₃-based single crystal substrate.

The present application is based on Japanese patent application No. 2014-039783filed on Feb. 28, 2014, the entire contents of which are incorporated herein by reference.

### BACKGROUND OF THE INVENTION

1. Field of the Invention

The invention relates to a semiconductor multilayer structure and a semiconductor element.

2. Description of the Related Art

A semiconductor multilayer structure is known which has a β-Ga₂O₃ single crystal substrate and a nitride semiconductor layer formed thereon by epitaxial growth (see e.g. JP-A-2013-251439).

JP-A-2013-251439 also discloses a semiconductor element, such as LED element, which is formed by using the semiconductor multilayer structure.

### SUMMARY OF THE INVENTION

In manufacturing a semiconductor element such as a light-emitting element and a transistor by using the semiconductor multilayer structure which has the β-Ga₂O₃-based single crystal substrate and the nitride semiconductor layer formed thereon by epitaxial growth, it is important to grow a high-quality nitride semiconductor layer on the β-Ga₂O₃-based single crystal substrate in order to reduce a leakage current in the semiconductor device and to improve the yield and the reliability.

It is an object of the invention to provide a semiconductor multilayer structure that includes a β-Ga₂O₃-based single crystal substrate and a nitride semiconductor layer with a high crystal quality formed thereon, as well as a semiconductor element including the semiconductor multilayer structure.

According to one embodiment of the invention, a semiconductor multilayer structure as set forth in [1] to [5] below is provided.
[1] A semiconductor multilayer structure, comprising:

a β-Ga₂O₃-based single crystal substrate comprising a main surface comprising a (−201), (101), (310) or (3-10) plane, the β-Ga₂O₃-based single crystal substrate being free from any twinning plane or further comprising a region free from any twinning plane, the region comprising a maximum width of not less than 2 inches in a direction perpendicular to an intersection line between a twinning plane and the main surface; and

a nitride semiconductor layer comprising an AlₓGa_{y}In_{z}N (0≦x≦1, 0≦y≦1, 0≦z≦1, x+y+z=1) crystal epitaxially grown on the β-Ga₂O₃-based single crystal substrate.
[2] The semiconductor multilayer structure according to [1], wherein the β-Ga₂O₃-based single crystal substrate is free from any twinned crystal.
[3] The semiconductor multilayer structure according to [2], wherein the β-Ga₂O₃-based single crystal substrate comprises a diameter of not less than 2inches.
[4] The semiconductor multilayer structure according to any one of [1] to [3], further comprising a buffer layer comprising an AlₓGa_{y}In_{z}N (0≦x≦1, 0≦y≦1, 0≦z≦1, x+y+z=1) crystal between the β-Ga₂O₃-based single crystal substrate and the nitride semiconductor layer.
[5] The semiconductor multilayer structure according to any one of [1] to [4], wherein the nitride semiconductor layer comprises a GaN crystal.

According to another embodiment of the invention, a semiconductor element as set forth in [6] below is provided.
[6] A semiconductor element, comprising the semiconductor multilayer structure according to any one of [1] to [5].

### Effects of the Invention

According to one embodiment of the invention, a semiconductor multilayer structure can be provided that includes a β-Ga₂O₃-based single crystal substrate and a nitride semiconductor layer with a high crystal quality formed thereon, as well as a semiconductor element including the semiconductor multilayer structure.

### BRIEF DESCRIPTION OF THE DRAWINGS

Next, the present invention will be explained in more detail in conjunction with appended drawings, wherein:

FIG. 1 is a vertical cross-sectional view showing a semiconductor multilayer structure in a first embodiment;

FIGS. 2A and 2B are plan views showing β-Ga₂O₃-based single crystal substrates in the first embodiment;

FIGS. 3A and 3B are cross sectional views showing β-Ga₂O₃-based single crystal substrates with a few twins;

FIG. 4 is an illustration diagram showing that a region with a different plane orientation appears on a main surface when the β-Ga₂O₃-based single crystal substrate contains twins;

FIG. 5 is a vertical cross-sectional view showing an EFG crystal manufacturing apparatus in the first embodiment;

FIG. 6 is a perspective view showing a state during growth of a β-Ga₂O₃-based single crystal in the first embodiment;

FIG. 7 is a perspective view showing a state of growing a β-Ga₂O₃-based single crystal to be cut into a seed crystal;

FIGS. 8A and 8B are optical microscope observation images of a surface of a GaN layer which is epitaxially grown on a β-Ga₂O₃ single crystal substrate having a main surface with a (101) plane area as well as a (−201) plane area;

FIGS. 9A and 9B are optical microscope observation images of a surface of a GaN layer which is epitaxially grown on a β-Ga₂O₃ single crystal substrate not containing twins and having a main surface only with a (−201) plane area;

FIGS. 10A and 10B are optical microscope observation images of a surface of a GaN layer which is epitaxially grown on a β-Ga₂O₃ single crystal substrate not containing twins and having a main surface only with a (101) plane area;

FIGS. 11A and 11B are optical microscope observation images of a surface of a GaN layer which is epitaxially grown on a β-Ga₂O₃ single crystal substrate containing multiple twins;

FIG. 12 is a vertical cross-sectional view showing an LED element in a second embodiment; and

FIGS. 13A and 13B are optical microscope observation images of surfaces of LED elements on a β-Ga₂O₃-based single crystal substrate, respectively showing an LED element formed in a region without twinning planes and another LED element formed in a region with twinning planes.

### DETAILED DESCRIPTION OF THE PREFERRED EMBODIMENTS

### First Embodiment

(Configuration of Semiconductor Multilayer Structure)

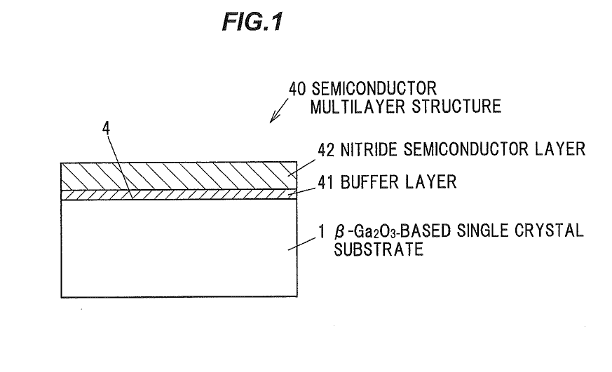

FIG. 1 is a vertical cross-sectional view showing a semiconductor multilayer structure 40 in the first embodiment. The semiconductor multilayer structure 40 has a β-Ga₂O₃-based single crystal substrate 1 and a nitride semiconductor layer 42 which is formed on a main surface 4 of the β-Ga₂O₃-based single crystal substrate 1 by epitaxial crystal growth. It is preferable to also provide a buffer layer 41 between the β-Ga₂O₃-based single crystal substrate 1 and the nitride semiconductor layer 42 as shown in FIG. 1 to reduce lattice mismatch between the β-Ga₂O₃-based single crystal substrate 1 and the nitride semiconductor layer 42.

The β-Ga₂O₃-based single crystal substrate 1 does not have twinning plane or has a region without twinning planes and with the maximum width of not less than 2 inches in a direction perpendicular to a line of intersection of a twinning plane and the main surface.

The main surface of the β-Ga₂O₃-based single crystal substrate 1 is preferably a surface with the oxygen atoms arranged in a hexagonal lattice, e.g., a (101) plane, a (−201) plane, a (310) plane or a (3-10) plane. This allows the nitride semiconductor layer 42 with flat surface to be epitaxially grown even on a thin buffer layer 41 (e.g., not more than 10 nm).

The details of the configuration of the β-Ga2O₃-based single crystal substrate 1 will be described later.

The buffer layer 41 is formed of an AlₓGa_{y}In_{z}N (0≦x≦1, 0≦y≦1, 0≦z≦1, x+y+z=1) crystal. On the β-Ga₂O₃-based single crystal substrate 1, the buffer layer 41 may be formed in an island pattern or in the form of film. The buffer layer 41 may contain a conductive impurity such as Si.

In addition, among AlₓGa_{y}In_{z}N crystals, an AlN crystal (x=1, y=z=0) is particularly preferable to form the buffer layer 41. When the buffer layer 41 is formed of the AlN crystal, adhesion between the β-Ga₂O₃-based single crystal substrate 1 and the nitride semiconductor layer 42 is further increased. The thickness of the buffer layer 41 is, e.g., 1 to 5 nm.

The buffer layer 41 is formed on the main surface 4 of the β-Ga₂O₃-based single crystal substrate 1 by, e.g., epitaxially growing an AlₓGa_{y}In_{z}N (0≦x≦1, 0≦y≦1, 0≦z≦1, x+y+z=1) crystal at a growth temperature of about 370 to 500° C.

The nitride semiconductor layer 42 is formed of an AlₓGa_{y}In_{z}N (0≦x≦1, 0≦y≦1, 0≦z≦1, x+y+z=1) crystal and is particularly preferably formed of a GaN crystal (y=1, x=z=0) from which a high-quality crystal is easily obtained. The thickness of the nitride semiconductor layer 42 is, e.g., 5 μm. The nitride semiconductor layer 42 may contain a conductive impurity such as Si.

The nitride semiconductor layer 42 is formed on the main surface 4 of the β-Ga₂O₃-based single crystal substrate 1 via the buffer layer 41 by, e.g., epitaxially growing an AlₓGa_{y}In_{z}N (0≦x≦1, 0≦y≦1, 0≦z>1, x+y+z=1) crystal at a growth temperature of about 1000° C.

Since the β-Ga_{2'O}₃-based single crystal substrate 1 does not have twinning plane or has a wide region without twinning planes, the nitride semiconductor layer 42 grown thereon does not have twinning plane in the entire region or in substantially the entire region and thereby has high crystal quality.

(Configuration of(β-Ga₂O₃-Based Single Crystal Substrate)

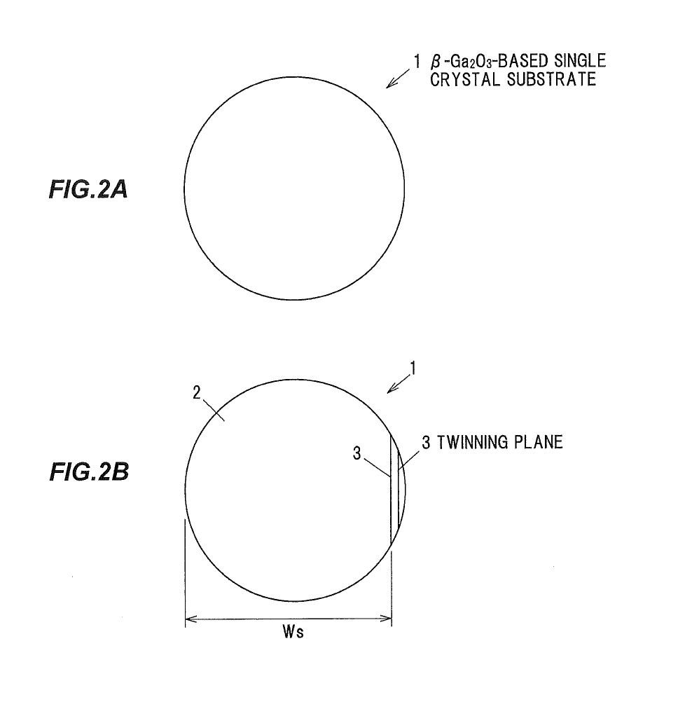

FIGS. 2A and 2B are plan views showing β-Ga₂O₃-based single crystal substrates 1 in the first embodiment. FIG. 2A shows a β-Ga₂O₃-based single crystal substrate 1 without twins and FIG. 2B shows a β-Ga₂O3-based single crystal substrate 1 with a few twins.

The β-Ga₂O₃-based single crystal substrate 1 is formed of a β-Ga₂O₃-based single crystal. The β-Ga₂O₃-based single crystal here is a β-Ga₂O₃ single crystal, or a β-Ga₂O₃ single crystal doped with an element such as Mg, Fe, Cu, Ag, Zn, Cd, Al, In, Si, Ge, Sn or Nb.

The β-Ga₂O₃-based crystal has a β-gallia structure belonging to the monoclinic system and typical lattice constants of the β-Ga₂O₃ crystal not containing impurities are a₀=12.23 Å, b₀=3.04 Å, c₀=5.80 Å, α=γ=90° and β=103.8°

A diameter of the β-Ga₂O₃-based single crystal substrate 1 without twins shown in FIG. 2A is preferably not less than 2 inches. The β-Ga₂O₃-based single crystal substrate 1 is cut from a β-Ga₂O₃-based single crystal which is grown by a below-described new method and does not contain or hardly contains twins. Therefore, it is possible to cut out a large substrate of not less than 2 inches not containing twins as the β-Ga₂O₃-based single crystal substrate 1.

The β-Ga₂O₃-based single crystal has high cleavability on a (100) plane, and twins with the (100) plane as a twinning plane (a plane of symmetry) are likely to be formed during crystal growth.

The β-Ga₂O₃-based single crystal substrate 1 with a few twins shown in FIG. 2B preferably has a diameter of not less than 2 inches and more preferably has a region 2 in which a width Ws is not less than 2 inches and twinning planes 3 are not present. The width Ws of the region 2 here is the maximum width in a direction perpendicular to a line of intersection of the twinning plane 3 and the main surface of the β-Ga₂O₃-based single crystal substrate 1. The width Ws of the region 2 is preferably larger since the region having the twinning planes 3 is not preferable as a base for epitaxial crystal growth.

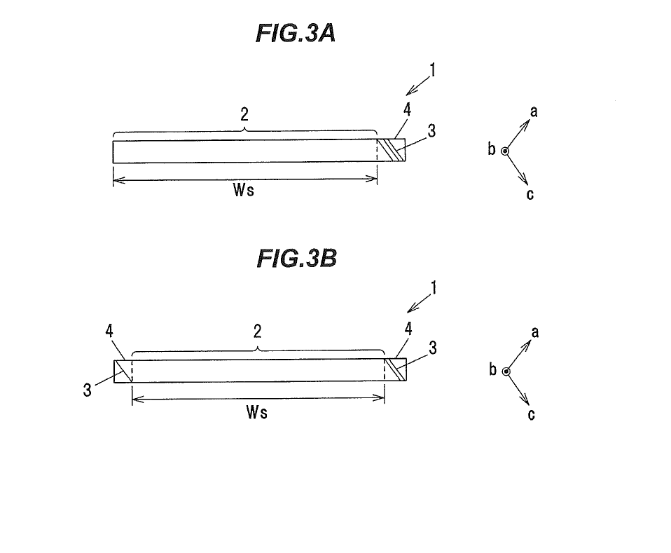

FIGS. 3A and 3B are cross sectional views showing the β-Ga₂O₃-based single crystal substrates 1 with a few twins. FIGS. 3A and 3B each show a cross section which passes through the center of the β-Ga₂O₃-based single crystal substrate 1 and is perpendicular to the twinning plane 3. Axes shown on the right side of the drawings indicate directions of a-, b- and c-axes of a β-Ga₂O₃ single crystal which is a base material of the β-Ga₂O₃-based single crystal substrate 1.

FIG. 3A shows an example of the region 2 when the twinning planes 3 are present on one side of the β-Ga₂O₃-based single crystal substrate 1 and FIG. 3B shows another example of the region 2 when the twinning planes 3 are present on both sides of the β-Ga₂O₃-based single crystal substrate 1. In FIGS. 3A and 3B, cross sections of the β-Ga₂O₃-based single crystal substrates 1 having a (−201) plane as the main surface are shown as an example.

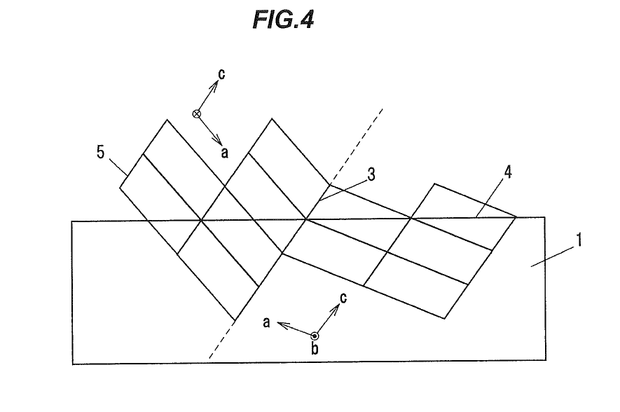

FIG. 4 is an illustration diagram showing that a region with a different plane orientation appears on the main surface 4 when the β-Ga₂O₃-based single crystal substrate 1 contain twins. Each quadrilateral 5 in the drawing schematically shows a unit cell of the β-Ga₂O₃ single crystal.

The crystal structure of twinned crystal is mirror-symmetrical with respect to a twinning plane which is a plane of symmetry. Therefore, planes of a β-Ga₂O₃-based single crystal appearing on the main surface 4 of the β-Ga₂O₃-based single crystal substrate 1 are oriented in different directions on one side and another side of a line of intersection of the main surface 4 and a twinning plane. When the plane orientation is, e.g., (101) in a region on one side, the plane orientation is (−201) in a region on the other side. In a similar manner, when the plane orientation is, e.g., (310) in a region on one side, the plane orientation is (3-10) in a region on the other side.

When the β-Ga₂O₃-based single crystal substrate 1 contains twins and plural regions having different plane orientations are present on the main surface 4, it is very difficult to epitaxially grow a high-quality nitride semiconductor layer 42 on the entire region. Obviously, it is not preferable to use a poor-crystal-quality region of the nitride semiconductor layer 42 to manufacture a semiconductor element such as LED element. It is also not preferable to use a region with twinning planes to manufacture a semiconductor element such as LED element.

Therefore, the β-Ga₂O₃-based single crystal substrate 1 is required to be free from twinning planes 3 and, in case of having the twinning planes 3, the β-Ga₂O₃-based single crystal substrate 1 is required to have a region without twinning planes 3 and with the maximum width of not less than 2 inches in a direction perpendicular to a line of intersection of the twinning plane 3 and the main surface 4.

(Method of Manufacturing (β-Ga₂O₃-Based Single Crystal Substrate)

Following is an example of a method of manufacturing the β-Ga₂O₃-based single crystal substrate 1 which does not contain twins or has a wide region without twins.

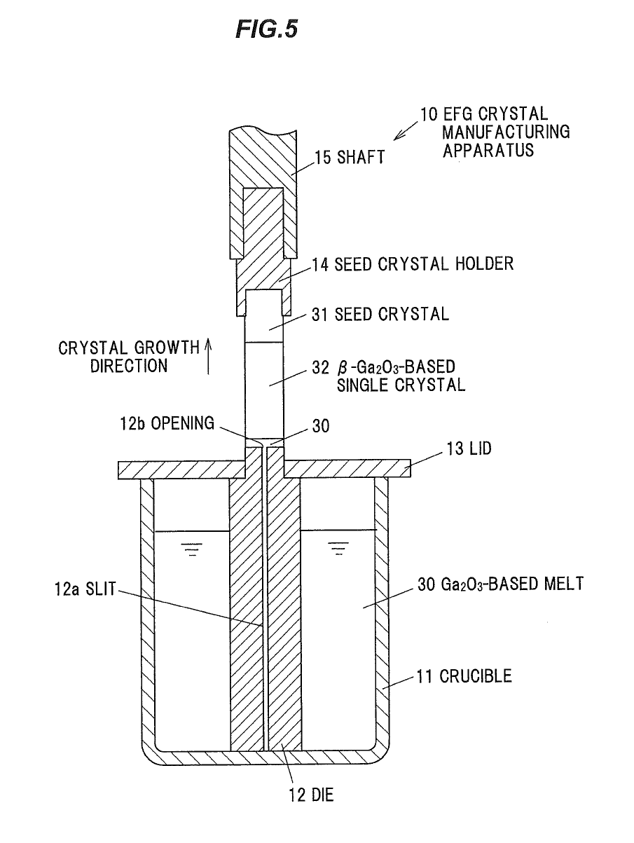

FIG. 5 is a vertical cross-sectional view showing an EFG (Edge Defined Film Fed Growth) crystal manufacturing apparatus 10 in the first embodiment.

The EFG crystal manufacturing apparatus 10 has a crucible 11 containing Ga₂O₃-based melt 30, a die 12 placed in the crucible 11 and having a slit 12a, a lid 13 covering an opening of the crucible 11 so that the top surface of the die 12 including an opening 12b is exposed, a seed crystal holder 14 for holding a seed crystal 31, and a shaft 15 vertically movably supporting the seed crystal holder 14.

The crucible 11 contains the Ga₂O₃-based melt 30 which is obtained by melting a Ga₂O₃-based raw material. The crucible 11 is formed of a highly heat-resistant material such as Ir capable of containing the Ga₂O₃-based melt 30.

The die 12 has the slit 12a to draw up the Ga₂O₃-based melt 30 in the crucible 11 by capillary action. The die 12 is formed of a highly heat-resistant material such as Ir in the same manner as the crucible 11.

The lid 13 prevents the high-temperature Ga₂O₃-based melt 30 from evaporating from the crucible 11 and further prevents the evaporated substances from attaching to members located outside of the crucible 11.

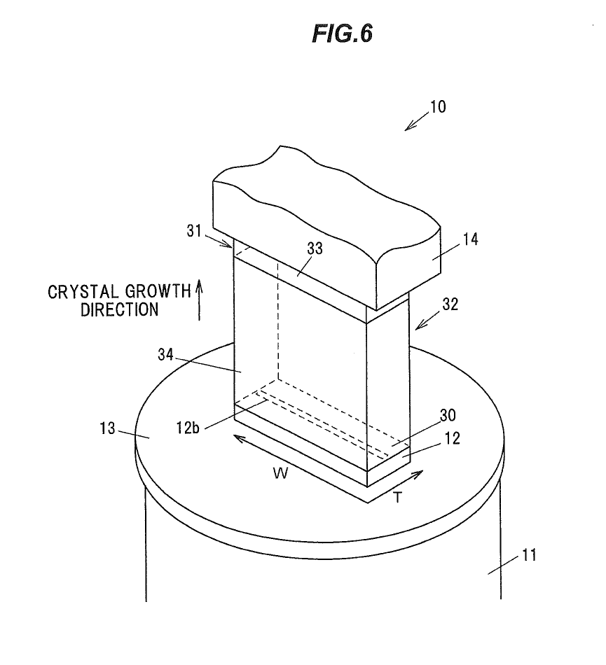

FIG. 6 is a perspective view showing a state during growth of a β-Ga₂O₃-based single crystal 32 in the first embodiment.

To grow the β-Ga₂O₃-based single crystal 32, firstly, the Ga₂O₃-based melt 30 in the crucible 11 is drawn up to the opening 12b of the die 12 through the slit 12a of the die 12, and the seed crystal 31 is then brought into contact with the Ga₂O₃-based melt 30 present in the opening 12b of the die 12. Next, the seed crystal 31 in contact with the Ga₂O₃-based melt 30 is pulled vertically upward, thereby growing the β-Ga₂O₃-based single crystal 32.

The seed crystal 31 is a β-Ga₂O₃-based single crystal which does not have or hardly has twinning planes. The seed crystal 31 has substantially the same width and thickness as the β-Ga₂O₃-based single crystal 32 to be grown. Thus, it is possible to grow the β-Ga₂O₃-based single crystal 32 without broadening a shoulder thereof in a width direction W and a thickness direction T.

Since the growth of the β-Ga₂O₃-based single crystal 32 does not involve a process of broadening a shoulder in the width direction W, twinning of the β-Ga₂O₃-based single crystal 32 is suppressed. Meanwhile, unlike the broadening of shoulder in the width direction W, twins are less likely to be formed when broadening the shoulder in the thickness direction T, and thus the growth of the β-Ga₂O₃-based single crystal 32 may involve a process of broadening a shoulder in the thickness direction T. However, in the case that the process of broadening a shoulder in the thickness direction T is not performed, substantially the entire β-Ga₂O₃-based single crystal 32 becomes a plate-shaped region which can be cut into substrates and this allows the substrate manufacturing cost to be reduced. Therefore, it is preferable to not perform the process of broadening a shoulder in the thickness direction T but to use a thick seed crystal 31 to ensure sufficient thickness of the β-Ga₂O₃-based single crystal 32 as shown in FIG. 6.

The orientation of a horizontally-facing surface 33 of the seed crystal 31 coincides with that of a main surface 34 of the ⊕-Ga₂O₃-based single crystal 32. Therefore, for obtaining the β-Ga₂O₃-based single crystal substrate 1 having, e.g., the (−201)-oriented main surface 4 from the β-Ga₂O₃-based single crystal 32, the β-Ga₂O₃-based single crystal 32 is grown in a state that the surface 33 of the seed crystal 31 is oriented to (−201).

Next, a method in which a wide seed crystal 31 with a width equivalent to the β-Ga₂O₃-based single crystal 32 is formed using a quadrangular prism-shaped narrow-width seed crystal will be described.

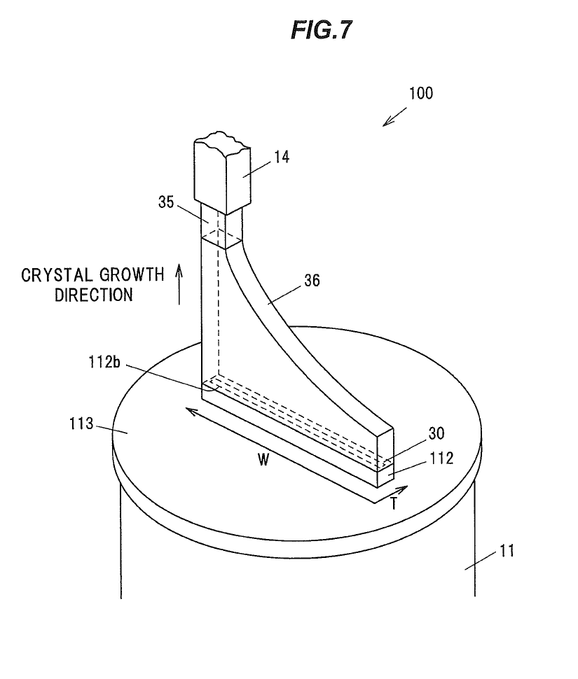

FIG. 7 is a perspective view showing a state of growing a β-Ga₂O₃-based single crystal 36 to be cut into the seed crystal 31.

The seed crystal 31 is cut from a region of the β-Ga₂O₃-based single crystal 36 not having or hardly having twinning planes. Therefore, a width (a size in the width direction W) of the β-Ga₂O₃-based single crystal 36 is larger than the width of the seed crystal 31.

Meanwhile, a thickness (a size in the thickness direction T) of the β-Ga₂O₃-based single crystal 36 may be smaller than the thickness of the seed crystal 31. In such a case, the seed crystal 31 is not cut directly from the β-Ga₂O₃-based single crystal 36. Instead, a β-Ga₂O₃-based single crystal is firstly grown from a seed crystal cut from the β-Ga₂O₃-based single crystal 36 while broadening a shoulder in the thickness direction T and is then cut into the seed crystal 31.

For growing the β-Ga₂O₃-based single crystal 36, it is possible to use an EFG crystal manufacturing apparatus 100 which has substantially the same structure as the EFG crystal manufacturing apparatus 10 used for growing the β-Ga₂O₃-based single crystal 32. However, width, or width and thickness, of a die 112 of the EFG crystal manufacturing apparatus 100 is/are different from that/those of the die 12 of the EFG crystal manufacturing apparatus 10 since the width, or width and thickness, of the β-Ga₂O₃-based single crystal 36 is/are different from that/those of the β-Ga₂O₃-based single crystal 32. The size of an opening 112b of the die 112 may be the same as the opening 12b of the die 12.

A seed crystal 35 is a quadrangular prism-shaped β-Ga₂O₃-based single crystal with a smaller width than the β-Ga₂O₃-based single crystal 36 to be grown.

To grow the β-Ga₂O₃-based single crystal 36, firstly, the Ga₂O₃-based melt 30 in the crucible 11 is drawn up to the opening 112b of the die 112 through a slit of the die 112, and the seed crystal 35 is then brought into contact with the Ga₂O₃-based melt 30 present in the opening 112b of the die 112 in a state that a horizontal position of the seed crystal 35 is offset in the width direction W from the center of the die 112 in the width direction W. In this regard, more preferably, the seed crystal 35 is brought into contact with the Ga₂O₃-based melt 30 covering the top surface of the die 112 in a state that the horizontal position of the seed crystal 35 is located at an edge of the die 112 in the width direction W.

Next, the seed crystal 35 in contact with the Ga₂O₃-based melt 30 is pulled vertically upward, thereby growing the β-Ga₂O₃-based single crystal 36.

The β-Ga₂O₃-based single crystal has high cleavability on the (100) plane as described above, and twins with the (100) plane as a twinning plane (a plane of symmetry) are likely to be formed in the shoulder broadening process during crystal growth. Therefore, it is preferable to grow the β-Ga₂O₃-based single crystal 32 in a direction in which the (100) plane is parallel to the growth direction of the β-Ga₂O₃-based single crystal 32, e.g., to grow in a b-axis direction or a c-axis direction so as to allow the size of a crystal without twins cut from the β-Ga₂O₃-based single crystal 32 to be maximized.

It is especially preferable to grow the β-Ga₂O₃-based single crystal 32 in the b-axis direction since the β-Ga₂O₃-based single crystal is liable to grow in the b-axis direction.

In the meantime, in case that the growing β-Ga₂O₃-based single crystal is twinned during the process of broadening a shoulder in a width direction, twinning planes are likely to be formed in a region close to the seed crystal and are less likely to be formed at positions distant from the seed crystal.

The method of growing the β-Ga₂O₃-based single crystal 36 in the first embodiment uses such twinning properties of the β-Ga₂O₃-based single crystal. In the first embodiment, since the β-Ga₂O₃-based single crystal 36 is grown in the state that the horizontal position of the seed crystal 35 is offset in the width direction W from the center of the die 112 in the width direction W, a region far from the seed crystal 35 is large in the β-Ga₂O₃-based single crystal 36, as compared to the case of growing the β-Ga₂O₃-based single crystal 36 in a state that the horizontal position of the seed crystal 35 is located on the center of the die 112 in the width direction W. Twinning planes are less likely to be formed in such a region and it is thus possible to cut out a wide seed crystal 31.

For growing the β-Ga₂O₃-based single crystal 36 using the seed crystal 35 and for cutting the β-Ga₂O₃-based single crystal 36 into a seed crystal, it is possible to use a technique disclosed in JP-B-2013-102599.

Next, an example method of cutting the grown β-Ga₂O₃-based single crystal 32 into the β-Ga₂O₃-based single crystal substrate 1 will be described.

Firstly, the β-Ga₂O₃-based single crystal 32 having a thickness of, e.g., 18 mm is grown and is then annealed to relieve thermal stress during single crystal growth and to improve electrical characteristics. The annealing is performed, e.g., in an inactive atmosphere such as nitrogen while maintaining temperature at 1400 to 1600° C. for 6 to 10 hours.

Next, the seed crystal 31 and the β-Ga₂O₃-based single crystal 32 are separated by cutting with a diamond blade. Firstly, the β-Ga₂O₃-based single crystal 32 is fixed to a carbon stage with heat-melting wax in-between. The β-Ga₂O₃-based single crystal 32 fixed to the carbon stage is set on a cutting machine and is cut for separation. The grit number of the blade is preferably about #200 to #600 (defined by JIS B 4131) and a cutting rate is preferably about 6 to 10 mm per minute. After cutting, the β-Ga₂O₃-based single crystal 32 is detached from the carbon stage by heating.

Next, the edge of the β-Ga₂O₃-based single crystal 32 is shaped into a circular shape by an ultrasonic machining device or a wire-electrical discharge machine Orientation flats may be formed at the edge of the circularly-shaped β-Ga₂O₃-based single crystal 32.

Next, the circularly-shaped β-Ga₂O₃-based single crystal 32 is sliced to about 1 mm thick by a multi-wire saw, thereby obtaining the β-Ga₂O₃-based single crystal substrate 1. In this process, it is possible to slice at a desired offset angle. It is preferable to use a fixed-abrasive wire saw. A slicing rate is preferably about 0.125 to 0.3 mm per minute.

Next, the β-Ga₂O₃-based single crystal substrate 1 is annealed to reduce processing strain and to improve electrical characteristics as well as permeability. The annealing is performed in an oxygen atmosphere during temperature rise and is performed in an inactive atmosphere such as nitrogen atmosphere when maintaining temperature after the temperature rise. The temperature to be maintained here is preferably 1400 to 1600° C.

Next, the edge of the β-Ga₂O₃-based single crystal substrate 1 is chamfered (bevel process) at a desired angle.

Next, the β-Ga₂O₃-based single crystal substrate 1 is ground to a desired thickness by a diamond abrasive grinding wheel. The grit number of the grinding wheel is preferably about #800 to #1000 (defined by JIS B 4131).

Next, the β-Ga₂O₃-based single crystal substrate is polished to a desired thickness using a turntable and diamond slurry. It is preferable to use a turntable formed of a metal-based or glass-based material. A grain size of the diamond slurry is preferably about 0.5 μm.

Next, the β-Ga₂O₃-based single crystal substrate 1 is polished using a polishing cloth and CMP (Chemical Mechanical Polishing) slurry until atomic-scale flatness is obtained. The polishing cloth formed of nylon, silk fiber or urethane, etc., is preferable. Slurry of colloidal silica is preferably used. The main surface of the β-Ga₂O₃-based single crystal substrate 1 after the CMP process has a mean roughness of about Ra=0.05 to 0.1 nm.

(Relation Between Twins in β-Ga₂O₃-Based Single Crystal Substrate and Quality of Nitride Semiconductor Layer)

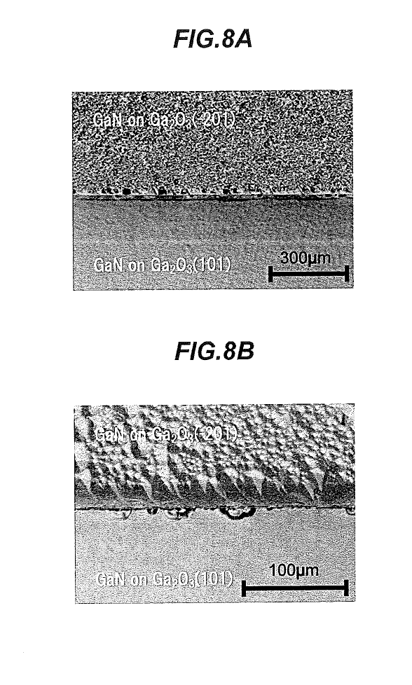

FIGS. 8A and 8B are optical microscope observation images of a surface of a GaN layer which is epitaxially grown on a β-Ga₂O₃ single crystal substrate having a main surface with a (101) plane area as well as a (−201) plane area. The magnification of the observation image in FIG. 8B is larger than that in FIG. 8A. The β-Ga₂O₃ single crystal substrate is an example of the β-Ga₂O₃-based single crystal substrate 1 in the first embodiment and the GaN layer is an example of the nitride semiconductor layer 42.

The line observed at the center of each of FIGS. 8A and 8B is a twinning plane formed on a surface of the GaN layer. The upper side of the twinning plane is a region formed on the (−201) plane area of the β-Ga₂O₃ single crystal substrate and the lower side of the twinning plane is a region formed on the (101) plane area.

As shown in FIGS. 8A and 8B, the GaN layer grown on the (101) plane area of the β-Ga₂O₃ single crystal substrate has good surface flatness while the GaN layer grown on the (−201) plane area has poor surface flatness (mirror surface is not obtained).

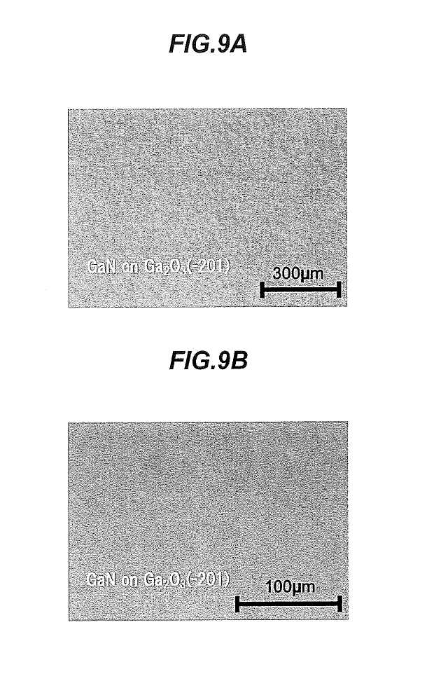

FIGS. 9A and 9B are optical microscope observation images of a surface of a GaN layer which is epitaxially grown on a β-Ga₂O₃ single crystal substrate not containing twins and having a main surface only with a (−201) plane area. The magnification of the observation image in FIG. 9B is larger than that in FIG. 9A.

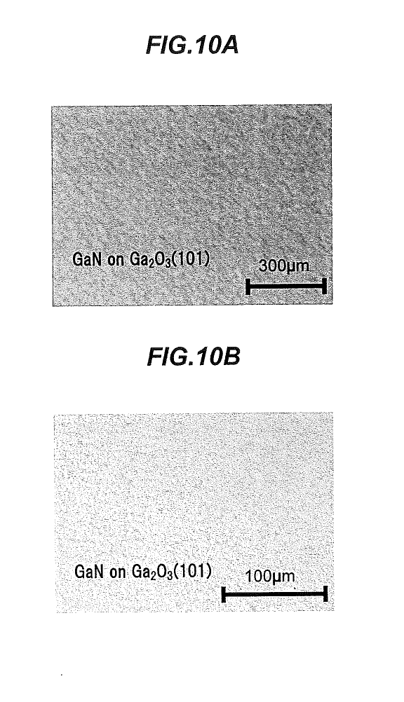

FIGS. 10A and 10B are optical microscope observation images of a surface of a GaN layer which is epitaxially grown on a β-Ga₂O₃ single crystal substrate not containing twins and having a main surface only with a (101) plane area.

As shown in FIGS. 9A, 9B, FIGS. 10A and 10B, in case that the β-Ga₂O₃ single crystal substrate does not contain twins, a GaN layer with highly uniform in-plane crystal quality and excellent surface flatness is obtained.

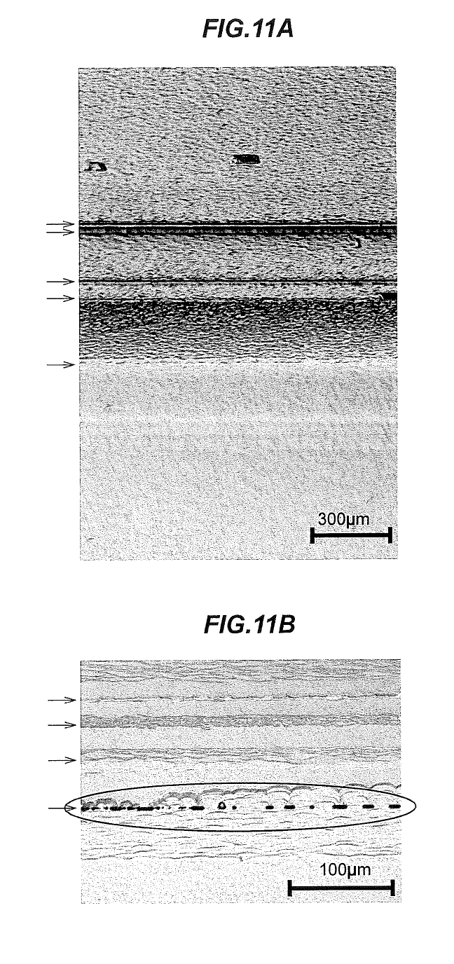

FIGS. 11A and 11B are optical microscope observation images of a surface of a GaN layer which is epitaxially grown on a β-Ga₂O₃ single crystal substrate containing multiple twins.

The arrows in FIGS. 11A and 11B point to positions of twinning planes formed in the GaN layer and appearing on a surface. On the surface of the GaN layer grown on the β-Ga₂O₃ single crystal substrate with twins, the continuity of crystal plane is interrupted by the twinning planes. In addition, in a region above a twinning plane which is encircled by an ellipse in FIG. 11B, pits or large level differences of several μm to several tens μm formed during CMP process or cleaning process due to a difference in etching rate between twinning planes are observed.

### Second Embodiment

The second embodiment is an embodiment of a semiconductor element including the semiconductor multilayer structure 40 in the second embodiment. An LED element will be described below as an example of such a semiconductor element.

(Configuration of Semiconductor Element)

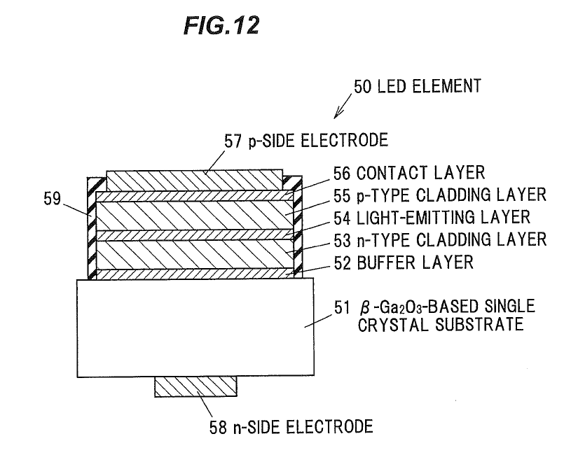

FIG. 12 is a vertical cross-sectional view showing an LED element 50 in the second embodiment. The LED element 50 has a β-Ga₂O₃-based single crystal substrate 51, a buffer layer 52 on the β-Ga₂O₃-based single crystal substrate 51, an n-type cladding layer 53 on the buffer layer 52, a light-emitting layer 54 on the n-type cladding layer 53, a p-type cladding layer 55 on the light-emitting layer 54, a contact layer 56 on the p-type cladding layer 55, a p-side electrode 57 on the contact layer 56 and an n-side electrode 58 on a surface of the β-Ga₂O₃-based single crystal substrate 51 opposite to the buffer layer 52.

Then, side surfaces of the laminate composed of the buffer layer 52, the n-type cladding layer 53, the light-emitting layer 54, the p-type cladding layer 55 and the contact layer 56 are covered with an insulating film 59.

Here, the β-Ga₂O₃-based single crystal substrate 51, the buffer layer 52 and the n-type cladding layer 53 are formed by respectively dividing or patterning the 0-Ga203-based single crystal substrate 1, the buffer layer 41 and the nitride semiconductor layer 42 which constitute the semiconductor multilayer structure 40 in the first embodiment. The thicknesses of the β-Ga₂O₃-based single crystal substrate 51, the buffer layer 52 and the n-type cladding layer 53 are respectively, e.g., 400 μm, 5 nm and 5 μm.

Addition of a conductive impurity allows the β-Ga₂O₃-based single crystal substrate 51 to have conductivity and it is thereby possible to use the β-Ga₂O₃-based single crystal substrate 51 to form a vertical-type semiconductor device as is the LED element 50 in which electricity is conducted in a thickness direction. In addition, the β-Ga₂O₃-based single crystal substrate 51 is transparent to light in a wide range of wavelength. Therefore, in a light-emitting device as is the LED element 50, it is possible to extract light on the β-Ga₂O₃-based single crystal substrate 51 side.

The n-type cladding layer 53, which is formed of the nitride semiconductor layer 42 of the semiconductor multilayer structure 40, has excellent crystal quality. Thus, the light-emitting layer 54, the p-type cladding layer 55 and the contact layer 56 which are formed on such an n-type cladding layer 53 by epitaxial growth also have excellent crystal quality. Therefore, the LED element 50 is excellent in leakage current characteristics, reliability and drive performance, etc.

The light-emitting layer 54 is composed of e.g., three layers of multi-quantum-well structures and a 10 nm-thick GaN crystal film thereon. Each multi-quantum-well structure is composed of an 8 nm-thick GaN crystal film and a 2 nm-thick InGaN crystal film. The light-emitting layer 54 is formed by, e.g., epitaxially growing each crystal film on the n-type cladding layer 53 at a growth temperature of 750° C.

The p-type cladding layer 55 is, e.g., a 150 nm-thick GaN crystal film containing Mg at a concentration of 5.0×10¹⁹/cm³. The p-type cladding layer 55 is formed by, e.g., epitaxially growing a Mg-containing GaN crystal on the light-emitting layer 54 at a growth temperature of 1000° C.

The contact layer 56 is, e.g., a 10 nm-thick GaN crystal film containing Mg at a concentration of 1.5×10²⁰/cm³. The contact layer 56 is formed by, e.g., epitaxially growing a Mg-containing GaN crystal on the p-type cladding layer 55 at a growth temperature of 1000° C.

For forming the buffer layer 52, the n-type cladding layer 53, the light-emitting layer 54, the p-type cladding layer 55 and the contact layer 56, it is possible to use TMG (trimethylgallium) gas as a Ga raw material, TMI (trimethylindium) gas as an In raw material, (C₂H₅)₂SiH₂(diethylsilane) gas as a Si raw material, Cp₂Mg (bis(cyclopentadienyl)magnesium) gas as a Mg raw material and NH₃ (ammonia) gas as an N raw material.

The insulating film 59 is formed of an insulating material such as SiO₂ and is formed by, e.g., sputtering.

The p-side electrode 57 and the n-side electrode 58 are electrodes in ohmic contact respectively with the contact layer 56 and the β-Ga₂O₃-based single crystal substrate 51 and are formed using, e.g., a vapor deposition apparatus.

The buffer layer 52, the n-type cladding layer 53, the light-emitting layer 54, the p-type cladding layer 55, the contact layer 56, the p-side electrode 57 and the n-side electrode 58 are formed on the β-Ga₂O₃-based single crystal substrate 51 (the β-Ga₂O₃-based single crystal substrate 1) in the form of wafer and the β-Ga₂O₃-based single crystal substrate 51 is then cut into chips of, e.g., 300μm square in size by dicing, thereby obtaining the LED elements 50.

The LED element 50 is, e.g., an LED chip configured to extract light on the β-Ga₂O₃-based single crystal substrate 51 side and is mounted on a CAN type stem using Ag paste.

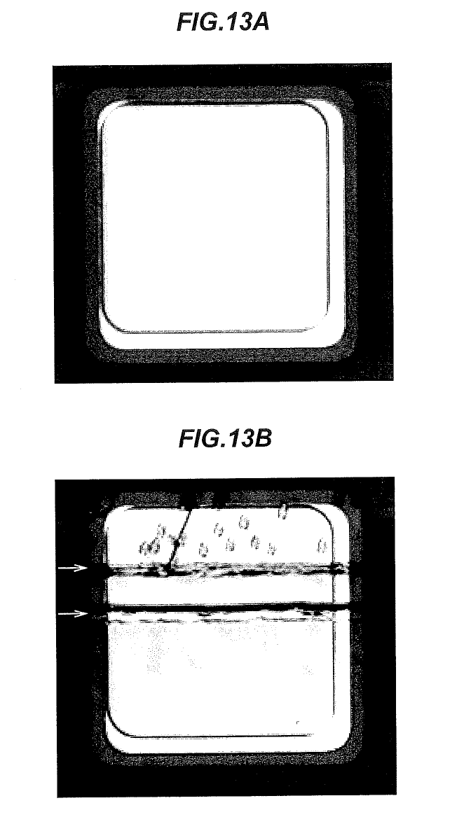

FIGS. 13A and 13B are optical microscope observation images of surfaces of LED elements 50 on the β-Ga₂O₃-based single crystal substrate 51, respectively showing an LED element formed in a region without twinning planes (hereinafter, referred to as LED element 50a) and another LED element formed in a region with twinning planes (hereinafter, referred to as LED element 50b).

The arrows in the drawing point to positions of twinning planes appearing on a surface of the LED element 50b. The LED elements 50a and 50b have a square planar shape of 300 μm×300 μm. The β-Ga₂O₃-based single crystal substrate 51 of the LED elements 50a and 50b is not separated to chip size yet at the time of observation and the below-described leakage current measurement.

In the LED elements 50a and 50b, the β-Ga₂O₃-based single crystal substrate 51 is a 400 μm-thick β-Ga₂O₃ single crystal substrate, the buffer layer 52 is a 5 nm-thick AlN crystal layer, the n-type cladding layer 53 is a 5 μm-thick GaN crystal layer, the light-emitting layer 54 has a multi-quantum-well structure composed of an 8 nm-thick GaN crystal film and a 2 nm-thick InGaN crystal film, the p-type cladding layer 55 is a 150 nm-thick GaN crystal layer, the contact layer 56 is a 10 nm-thick GaN crystal layer, the p-side electrode 57 has a structure formed by laminating a 500 nm-thick Ag film, a 1 pm-thick Pt film and a 3 μm-thick AuSn film, and the n-side electrode 58 has a structure formed by laminating a 50 nm-thick Ti film and a 1 μm-thick Au film.

Current values (magnitude of leakage current) when applying forward voltage of 2.0 V between the p-side electrode 57 and the n-side electrode 58 were 0.03 μA for the LED element 50a and not less than 1000 μA (equal or greater than the measurement limit of a measuring device) for the LED element 50b. Also, as shown in FIG. 13B, defects were formed on pits in one of the regions divided by the twinning planes (in a region on the upper side of the drawing). In addition, when the light-emitting state of the LED elements 50a and 50b was checked, the LED element 50a emitted light but the LED element 50b did not emit light.

On the twinning planes in the β-Ga₂O₃-based single crystal substrate 51, stress is likely to be concentrated and cracking or breaking is likely to occur when strain is generated. In addition, level differences formed due to a difference in etching rate between twinning planes or those formed due to variation in growth rate in the vicinity of the tinning planes, etc., are considered to cause cracks on the β-Ga₂O₃-based single crystal substrate 51 during the post-process.

The percentage of the LED elements 50 completed without cracking of the β-Ga₂O₃-based single crystal substrate 51 after processes until formation of the p-side electrode 57 and the n-side electrode 58 was 94% (75 out of 80) when the β-Ga₂O₃-based single crystal substrate 51 did not contain twins, and 49% (26 out of 58) when the β-Ga₂O₃-based single crystal substrate 51 contained twins.

Although the LED element 50 which is a light-emitting element has been described as an example of a semiconductor element including the semiconductor multilayer structure 40 of the first embodiment, the semiconductor element is not limited thereto and may be other light-emitting elements such as laser diode or other elements such as transistor. Even when using the semiconductor multilayer structure 40 to form another element, it is also possible to obtain a high-quality element since layers formed on the semiconductor multilayer structure 40 by epitaxial growth have excellent crystal quality in the same manner as the LED element 50.

(Effects of the Embodiments)

In the first embodiment, by processing a high-quality β-Ga₂O₃-based single crystal grown using a growth method described in the first embodiment, it is possible to obtain a β-Ga₂O₃-based single crystal substrate with excellent crystal quality which does not contain twins or has a wide region without twins. In addition, by epitaxially growing a nitride semiconductor crystal on such a β-Ga₂O₃-based single crystal substrate, it is possible to form a nitride semiconductor layer with excellent crystal quality not containing twins or containing only a few twins and thereby to obtain a high-quality semiconductor multilayer structure.

In the nitride semiconductor layer not containing twins or containing only a few twins, in-plane crystal quality is highly uniform. In detail, there is no, or a few, low-quality portions which grow in a region with a different plane orientation from the original plane orientation of the main surface of the β-Ga₂O₃-based single crystal substrate. In addition, it is possible to avoid troubles such as interruption of the continuity of the nitride semiconductor layer by twinning planes or formation of defects on pits.

In the second embodiment, use of the high-quality semiconductor multilayer structure obtained in the first embodiment allows high-quality films to be epitaxially grown thereon and it is thereby possible to obtain a high-performance semiconductor element with high crystal quality. This reduces faulty elements such as elements with large leakage current or light-emitting elements failing to emit light and also drastically reduces such faulty elements that the β-Ga₂O₃-based single crystal substrate is broken during electrode forming process, etc., and it is thus possible to significantly improve production yield of semiconductor element.

It should be noted that the invention is not intended to be limited to the embodiments and the various kinds of modifications can be implemented without departing from the gist of the invention.

In addition, the invention according to claims is not to be limited to embodiments. Further, it should be noted that all combinations of the features described in the embodiments are not necessary to solve the problem of the invention.

What is claimed is:

1. A semiconductor multilayer structure, comprising:
a β-Ga₂O₃-based single crystal substrate comprising a main surface comprising a (−201), (101), (310) or (3-10) plane, the β-Ga₂O₃-based single crystal substrate being free from any twinning plane or further comprising a region free from any twinning plane, the region comprising a maximum width of not less than 2 inches in a direction perpendicular to an intersection line between a twinning plane and the main surface; and
a nitride semiconductor layer comprising an AlₓGa_{y}In_{z}N (0≦x≦1, 0≦y≦1, 0≦z≦1, x+y+z=1) crystal epitaxially grown on the β-Ga₂O₃-based single crystal substrate.

2. The semiconductor multilayer structure according to claim 1, wherein the β-Ga₂O₃-based single crystal substrate is free from any twinned crystal.

3. The semiconductor multilayer structure according to claim 2, wherein the β-Ga₂O₃-based single crystal substrate comprises a diameter of not less than 2 inches.

4. The semiconductor multilayer structure according to claim 1, further comprising a buffer layer comprising an AlₓGa_{y}In_{z}N (0≦x≦1, 0≦y≦1, 0≦z≦1, x+y+z=1) crystal between the β-Ga₂O₃-based single crystal substrate and the nitride semiconductor layer.

5. The semiconductor multilayer structure according to claim 2, further comprising a buffer layer comprising an AlₓGa_{y}In_{z}N (0≦x≦1, 0≦y≦1, 0≦z≦1, x+y+z=1) crystal between the β-Ga₂O₃-based single crystal substrate and the nitride semiconductor layer.

6. The semiconductor multilayer structure according to claim 3, further comprising a buffer layer comprising an AlₓGa_{y}In_{z}N (0≦x≦1, 0≦y≦1, 0≦z≦1, x+y+z=1) crystal between the β-Ga₂O₃-based single crystal substrate and the nitride semiconductor layer.

7. The semiconductor multilayer structure according to claim 1, wherein the nitride semiconductor layer comprises a GaN crystal.

8. The semiconductor multilayer structure according to claim 2, wherein the nitride semiconductor layer comprises a GaN crystal.

9. The semiconductor multilayer structure according to claim 3, wherein the nitride semiconductor layer comprises a GaN crystal.

10. The semiconductor multilayer structure according to claim 4, wherein the nitride semiconductor layer comprises a GaN crystal.

11. A semiconductor element, comprising the semiconductor multilayer structure according to claim 1.

12. A semiconductor element, comprising the semiconductor multilayer structure according to claim 2.

13. A semiconductor element, comprising the semiconductor multilayer structure according to claim 3.

14. A semiconductor element, comprising the semiconductor multilayer structure according to claim 4.

15. A semiconductor element, comprising the semiconductor multilayer structure according to claim 7.
